(19) United States
(12) Patent Application Publication
(10) Pub. No.: US 2011/0130982 A1
(43) Pub. Date: Jun. 2, 2011

(54) Monitoring System for Power Grid Distributed Power Generation Devices

(75) Inventors: Michael Haag, Hauptstrasse (DE); Nils Haustein, Schomsheimer (DE); Rainer Klaus Krause, Raunheimerstr (DE); Thorsten Muehge, Buchenweg (DE); Joerg Weyerthaeuser, Auf dem Teich (DE)

(73) Assignee: International Business Machines Corporation, Armonk, NY (US)

(21) Appl. No.: 12/953,850

(22) Filed: Nov. 24, 2010

(30) Foreign Application Priority Data
Nov. 30, 2009 (DE) 09177454.7

(51) Int. Cl. G06F 19/00; G01R 21/00

(52) U.S. Cl. 702/62

(57) ABSTRACT

The invention relates to an autonomously working monitoring system (10), a method for monitoring and maintenance of power grid distributed power generation devices (14) and a related computer program product. The system comprises at least one power performance monitoring unit (12) for monitoring, analyzing and storing at least power performance data (70) of at least one power generation device (14);
at least one power generation device (14) comprising at least one power generation module (16) for generation of electric power and at least one inverter module (18) for feeding in electric power of said power generation module (16) to a power grid (20);
and an external network (22) connecting one or more power generation devices (14) with said power performance monitoring unit (12).

The power generation device (14) further comprises
at least one data acquisition module (24) for measuring of power output of each power generation module (16);
at least one inverter measuring module (26) for measuring of power output of said inverter (18) to the power grid (20);
a data interface module (28) in power line communication with said data acquisition module (24), and in communication with said inverter measuring module (26) and said external network (22) for sending power performance data (70) of said power generation device (14) to said power performance monitoring unit (12) including power generation module ID (66) and inverter ID (68), and/or for autonomously sending a maintenance notice for requesting a maintenance action based on at least a specific power performance pattern.

### FIELD OF THE INVENTION

The present invention relates to a monitoring system for power grid distributed power generation devices for autonomous monitoring, analyzing and maintaining of performance of said power generation devices.

Furthermore, the present invention relates to a method for autonomous maintenance of distributed power generation devices in a power grid.

### BACKGROUND OF THE INVENTION

Distributed power generation devices, especially renewable power generation devices like solar cell modules, wind energy generators or other renewable energy sources feeding electric power into a power grid are difficult to monitor and maintain by a centralized monitoring unit. Especially small distributed power generation devices, such as solar module installations running on private initiative (being installed on a roof of a house) are lacking performance visibility which can be used for planning and implementing maintenance actions, for instance cleaning solar module surfaces, preventing shading effects due to tree growth or adjusting orientation due to season-related fluctuations in the course of the sun. For instance a solar cell power generation device, when once installed, is not readily accessible for maintenance and testing, whereby a technician is required to climb onto the roof of a house or to access the house for monitoring power output of each solar module. Thus, efforts and costs for regular monitoring and maintenance actions of such distributed power generation devices in a widely ramified power grid are proportional to the number of power generation devices, whereby typical installation numbers of solar cells in a medium-sized city exceed the number of several hundred solar cell module installations.

For the aforementioned number of installations in a medium-sized city, said monitoring and maintenance actions are costly and time-consuming, requiring temporary deactivation of solar cell power generation devices, and are therefore economically detrimental.

WO 2006/117551 A2 reveals a power generation device in the form of a photovoltaic cell, whereby a sensor for sending the value of at least one parameter indicative of the operation of the photovoltaic module, transmits data of the value via an electronic communication device to a remote device. In this way, parameters indicating current or temperature of one or several photovoltaic modules are transmitted to a remote device displaying power performance of each photovoltaic module. Thus this document reveals a monitoring system for monitoring power performance of individual photovoltaic-based power generation devices, whereby monitoring is performed “on-line”. The proposed system is only capable of monitoring performance of individual photovoltaic modules but is not capable of monitoring performance of a power inverter feeding electric power into a power grid.

### SUMMARY OF THE INVENTION

It is an object of the present invention to provide an autonomous monitoring system and a method for autonomous maintenance of distributed power generation devices providing detailed data and performance visibility for enhanced management of power generation devices. The system and method enables proactive response to system problems or to reactively perform corrective actions. Typical problems of power generation devices, such as device degradation and other fallout criteria, such as shadowing effects and contamination, must be determined quickly and resolved. Accordingly, vital components of power generation, such as power generation modules and power inverters, should be monitored independently, and each power generation device should collect and provide monitoring and maintenance data autonomously without the need of an “on-line” connection to a centralized power performance monitoring unit.

These objectives are achieved by the features of the independent claims. The other claims and the specification disclose advantageous embodiments of the invention.

According to the present invention, a monitoring system for power generation devices in a distributed power grid, includes a power performance monitoring unit for monitoring, analyzing and storing power performance data of power generation devices; a power generation device, including a power generation module for generation of electric power with an inverter module for feeding generated electric power into a power grid; and an external network connecting one or more power generation devices with the power performance monitoring unit. The power generation device also includes at a data acquisition module (DAM) for measuring power output data of each power generation module, an inverter measuring module for measuring power output of the inverter to the power grid, and a data interface module (DDI) in power line communication with the data acquisition module, and in communication with the inverter measuring module and the external network for sending power performance data of the power generation device to the power performance monitoring unit, including power generation module ID and inverter ID, and/or for autonomously sending a maintenance notice for requesting a maintenance action based on a specific power performance pattern.

Of course, performance data other than related to power performance can also be stored. In addition, other data, such as temperature, sun light intensity, humidity, position of the sun etc. can be measured by the DAM.

The inverter measuring module can preferably be also in electrical communication with the DDI via power line communication, but other forms of communication such als LAN-connection, serial or parallel data bus and similar connection wiring can also be used.

The autonomous monitoring system includes a power performance monitoring unit for monitoring, analyzing and storing data of one or several power generation devices distributed in a power grid. The power performance monitoring unit can also include sensing elements for monitoring, analyzing and storing other physical data of the power generation device like temperature, wind velocity and direction, sun light intensity and sun light angle, humidity, transparency of a solar module covering surface, etc. The autonomous monitoring system can initiate monitoring actions by sending monitoring notices to a power grid provider or a user indicating source of malfunction of a power generation device. Each power generation device comprises one or several power generation modules for generating electric energy, particularly DC electric energy and at least one inverter module for converting the generated electric energy into appropriate electric energy for feeding the energy into a power grid, particularly an AC power grid. Finally, an external network connects the one or several power generation devices with the at least one power performance monitoring unit.

Each power generation device includes a data acquisition module (DAM) being connected to the power generation device, for sensing power performance data and optional other physical data of the power generation device, like temperature, wind speed, sun light intensity, cloudiness, position of the sun, degree of contamination of a solar module surface, etc. The DAM can be embedded in an adapter fitting between the module backside plug and the connector going to the inverter.

Furthermore each power generation device includes an inverter measuring module for measuring power output of the inverter to the power grid, especially frequency, voltage and current of the inverter, and a data interface module (DDI) connected to the data acquisition module, the inverter measuring module and the external network, whereby the data interface module (DDI) is centrally installed within the power generation device and is connected via an internal network with the DAMs and the inverter measuring module. The DDI sends power performance data of the inverter and of each power generation module to the power performance monitoring unit identifying the power generation module and the inverter by specific ID's (Identification Numbers) relating to a DAM or an inverter measuring module. Additionally and also alternatively the DDI autonomously sends a maintenance notice for requesting a maintenance action based on at least a specific power performance pattern. A specific power performance pattern can be based on a set of historical power performance data comparing actual power performance with power performance of comparable former times like a year ago, yesterday, last four weeks, etc. or can be based on actual power performance of neighboring power generation modules or can be based on a mixture of both, historical data and actual data of neighboring power generation modules. If the DDI detects a gradual or significant change of power performance, like gradual worsening of power performance over time or abrupt break down of power output, the DDI can determine the source of such power performance change (shadowing effects, soiling of solar module surface, electrical short circuit of inverter etc) and can autonomously create and send a maintenance notice over the external network for requesting a maintenance action for reestablishing power performance of said power generation module.

Thereby, the performance of any power generation device is available in real-time, wherein in case of an incidence or problem, the provider can react immediately and additional costs or damage can be reduced. With the temperature and other physical data from the module, additional data is available for degradation monitoring. For instance information about the position of the sun allows correlation of power performance with sun light angle and also allows optimization of a solar module's orientation towards the sun. Wind velocity and wind direction data helps to predict mechanical stress to a power generation module and can indicate mechanical overload. By providing the power generation module ID and the inverter ID, individualized information is provided, indicating which component of which power generation devices suffers from power degradation or from malfunction. Therefore, specific maintenance actions can be carried out reducing costs and time of the service maintenance team. The entire performance data of one or all power generation devices being connected to the system can be viewed centrally by accessing a power performance monitoring unit, especially via a network, such as the internet, power line network or a wireless network, preferably an IEEE-Standard 802.16 such as WiMax by a user or a power grid provider and can be stored in a repository. Thus, the invention proposes a smart solution to manage renewable energy sources, here as an example a photovoltaic solar module, effectively and in real-time. In this way, optimal power performance can be achieved and costs can be optimized, and the grid can be managed smarter.

According to a favourable embodiment, the power generation module can be a DC power generation module, preferably a renewable DC power generation module, particularly a solar cell module, and the inverter can be a DC/AC inverter, preferably a three-phase inverter. The renewable power generation modules provide only small amounts of electric power, so that a typical power grid comprises a large number of distributed power generation devices, such as photovoltaic modules or wind energy generators. Especially solar cell modules are widely distributed in private housing and are fixed to roofs or walls facing the sun. Typical inverters convert module generated DC power into electric AC power or convert AC power of arbitrary frequency into AC power having a fixed frequency, whereby the inverter comprises typically three power semiconductor-equipped full-bridges, typically IGBT-bridges, for converting DC current into AC current. Monitoring both, the DC power generation module and the inverter provides detailed information on malfunction sources of all vital components of a power generation device and helps to maintain and repair power generation devices in short time and reduced costs.

According to another favourable embodiment, each power generation module may include one or more power generation cells, preferably solar cells, and a DAM can measure power output of at least one cell or a group of cells of the power generation module. Typically, solar cell modules include one or more cells, whereby a malfunction of one cell decreases the overall output of the whole solar cell module. A short-circuit, decreased power performance or open end of one cell can also lead to a decreased output or breakdown of the whole module. Therefore, it is highly advantageous that a data acquisition module not only measures overall power output of a module but also measures output of each individual cell or a group of cells, whereby the cells can also comprise clusters of multiple cells. Other failure indicators might be in favor to, like cell or module temperature, full or partial shadowing effects due to tree growth or misalignment of a cell or a module in contrast to the way of the sun, etc. In this way, the source for power degradation of a solar cell module can be identified and the solar cell modules can be repaired or selectively replaced, applying preventive maintenance.

According to a favourable embodiment of the present invention, at least a DAM and at least an inverter measuring module can output digital power performance data comprising voltage and current values and can be connected to a DDI via a power line communication (PLC) channel, also known as power line digital subscriber line (PDSL). Thus already existing power lines transporting generated electric power from a power generation module to an inverter can be used for a power line communication of said power performance date. Additional wiring or additional communication channels for an internal network transferring data of data acquisition module and inverter measuring module to the data interface module is not required. Power line communication allows digital data indicating power performance, such as voltage or current values of a power generating module or inverter to be transferred to the DDI via a conductor also used for electric power transmission. Thereby RF frequency modulated digital information being fed by a DAM or inverter measuring module into said power line can being received by an RF demodulator of a DDI. Specifically, a DAM or an inverter measuring module impresses a modulated carrier signal on a wiring system of power lines comprising power performance data and ID of a power generation module or an inverter. As such a DAM and/or inverter measuring module should comprise an RF modulator and a DDI should comprise an RF demodulator for modulating and demodulating said digital signals on the modulated carrier signal.

According to a favourable embodiment, a DDI can include a power performance data memory for storing power performance data of at least one DAM and/or inverter measuring module. The DDI can store historically collected power performance data and optionally other physical data of one or all connected DAMs and/or inverter measuring modules. Thereby, the DDI does not need to hold an “on-line” permanent connection to a power performance monitoring unit and can exchange power performance data using a burst data transfer mode therefore providing at least a temporary buffer storage for collecting and storing power performance data.

According to another favourable embodiment, a DDI can comprise a power performance analyzing unit for analyzing power performance data of at least one DAM and/or inverter measuring module based on at least a specific power performance pattern, and for creating and sending power performance data and/or a maintenance notice over an external network to a power performance monitoring unit. According to this embodiment, a DDI can analyze power performance data of a DAM and/or of an inverter measuring module. In this way, the power performance of a power generation module can be analyzed. Analyzing power performance is based on a specific pattern, such as historical power performance data of e.g. a year ago, yesterday or an average of power output of the last ten days or can be power performance data of neighboring power generation modules. When a discrepancy between actual and previously monitored power performance data or between a power output in comparison to neighboring comparable power generation modules can be detected indicating a degradation or malfunction, the DDI can create and send a maintenance notice indicating the source of the malfunction over an external network to a power performance monitoring unit to inform a maintenance service team to repair or replace the indicated parts of the power generation device.

According to a favourable embodiment, a power performance monitoring unit can be implemented on a network application server, especially a web application server. Autonomous updating, monitoring and evaluation of power performance data can be achieved and maintenance notices can be provided over a network. A network application server, especially a web application server can autonomously request power performance data of a DDI of one or more power generation devices in communication with the external network. In this way, a power performance monitoring unit receives power performance data or maintenance notices of at least one power generation device and can autonomously provide a monitoring, noticing or alarming service provided by the network application sever. The network application server can be adapted to automatically inform a maintenance service as a result of a received maintenance notice or can analyze performance data to generate a maintenance notice thus informing a maintenance service of a type of malfunction and ID of a power generation device, ID of a power generation module and/or ID of an inverter causing the malfunction.

According to another favourable embodiment, a power performance monitoring unit may include a power generation module database for storing power performance data and/or maintenance notice of at least one power generation device over a period of time. In addition, a power performance monitoring unit may further include a maintenance analyzing unit for analyzing power performance data and based on the result of the analysis can generate a maintenance notice concerning a malfunction of a power generation device. The power performance monitoring unit can store performance data received via said external network for generation of module database entries and can also store maintenance notices being sent by a DDI of a power generation device. In this way, a power performance monitoring unit can store historical data of the performance of a power generation device and can provide a history of power generation device-related maintenance notices indicating service life of said power generation device. Furthermore, the performance monitoring unit may include a maintenance analyzing unit which can analyze power performance data or maintenance notices received from one, several or all power generation devices connected to the external network and can generate and signal a maintenance notice of a power generation device. In this way, independent, alternative or additional to autonomously working DDIs a power performance monitoring unit can analyze performance data and can create and send a maintenance notice, whereby an update of an analyzing method can be performed centrally in a power performance monitoring unit.

Another aspect of the invention concerns a method for autonomous maintenance of distributed power generation devices in a power grid. The method includes the steps of accessing power performance data from each of one or more DAMs via power line communication and each of one or more inverter measuring modules. Accessing power performance data is realized through power line communication, a DDI; storing, analyzing and autonomously sending power performance data and/or maintenance notice based on at least a power performance pattern.

In other words, the method proposes to retrieve power performance data of each of one or more data acquisition modules via power line communication and each of one or more inverter measuring modules by a DDI via an internal network of a power generation device. The DDI stores analyzes and sends power performance data or a maintenance notice to at least one power performance monitoring unit via an external network. The DDI sends at least some of the performance data and maintenance notices concerning at least one power generating module or power inverter via an external network to a power performance monitoring unit, whereby a maintenance action assigned to a generated maintenance notice is triggered by the power performance monitoring unit. The maintenance notice is autonomously generated by comparing actual power performance data with a power performance pattern, taking historical power performance output or output of neighboring power generation modules into. In this way, the DDI receives power performance data regarding all vital elements of a power generating device, stores the data and can generate a maintenance notice in case the power performance data severely deviates from historical data or performance data patterns. A maintenance notice indicates a certain malfunction cause which can be assigned to a specific maintenance action for eliminating the cause of the malfunction. For instance, a shadowing effect due to tree growth causing a gradual degradation of power performance of a certain solar cell module during several weeks, especially in springtime can trigger a tree cutting action for restoring power performance of the affected solar cell module.

According to a favourable embodiment of the inventive method, accessing power performance data from at least one DAM and/or inverter measuring module by a DDI can be performed using a packet-oriented data protocol. Similar to a TCP/IP protocol, each packet includes a packet header, a source address, a power performance data block, including at least voltage and current values, optionally a module performance data block, like temperature, sun light intensity, wind velocity and direction, humidity, etc. and a packet trailer. A packet-oriented data protocol for transferring power performance data from a DAM and/or an inverter measuring module to a DDI, particularly by a power line communication channel, using a digital coding of the power performance data can provide a dense information transfer. The packet data can easily be forwarded by the DDI via an external network to a power performance monitoring unit. The source address can utilize a source ID, which means an ID of a data acquisition module or an ID of a inverter measuring module, the power performance block may include information about voltage values, current values or outputted power and eventually other technical information, such as temperature, peak values, hours of operation per day, days of service since last service interval, etc. and the packet header and packet trailer can include additional information as destination address, type of data packet, time stamp or check sum for checking data integrity.

According to a favourable embodiment, accessing power performance data and/or sending power performance data and/or maintenance notices can be performed either periodically or by request from a DDI or a power performance monitoring unit, respectively. In certain cases, a DAM and/or inverter measuring module can send power performance data regularly at fixed time intervals to a DDI, and said DDI can also send power performance data or maintenance notices on a regular basis via an external network to a performance monitoring unit. In other cases, for reducing data traffic and for accessing updated information only upon request, it can be favourable to initiate an access of power performance data and send data and maintenance notices via said external network to a power performance monitoring unit only upon request in a burst data mode, thus providing updated data only when needed and reducing data traffic.

According to a favourable embodiment of the present invention, power performance data and/or maintenance notices of at least one power generation module can be accessed through a network, preferably internet, power line network or a wireless network, preferably a IEEE-Standard 802.16 such as WiMax, by a network application, preferably a web application hosted by a power performance monitoring unit. Power performance data received by the power performance monitoring unit can be accessed in several ways, e.g. by using a terminal console having direct access to the power performance monitoring unit. In case that the power performance monitoring unit is connected to a network, preferably the same external network which connects the power performance monitoring unit with distributed power generating devices, an access to data stored in the power performance monitoring unit can be provided by a network application, and in case that the network is an internet network by a web application which is hosted by the power performance monitoring unit. In this case, a web application provides access to various data stored in the power performance monitoring unit without installing additional software on client computers. Thus, no local software installations on the consumer side are required and a simple web setup with a simple registration and log-in can be configured for accessing information on the behavior of the power generating devices distributed in the power grid. In this way, information across the entire power pool—distributed locally or countrywide—can be used, and a benchmark of installations close-by or similar installations can be calculated, whereby a warning in case of an unexpected or significant deviation from average power performance can be generated. In economical terms, if a business case scenario relating to distributed power generation devices in a power grid shall be investigated for project management, financing and assurance analysis, a web-based installation can provide benchmark information with real data, whereby ROI (Return On Investment) analysis can be based upon real power performance data, enabling a more reliable calculation of ROI. Furthermore performance data is based on an independent database and not supplier specific, and a cheaper assurance tariff can be available if this application is used. Manufacturers of power generation devices can access and analyze independent large field data, whereby a ranking of different kinds of power generating devices is possible. The system's downtime can be minimized due to early warning features and information on comparable power generation devices close-by can be used to exchange experience data. In communities, ideal locations for renewable energy assets, especially on public buildings or premises, as well as potential operators can easily be identified. Furthermore, an early warning system through e-mail, SMS or web notice can be installed in case of a deviation of the power performance from comparable installations and in case of deviations from specified and expected performance can be installed. A transparent web reporting gives information on the trend of the own installation and the power performance versus comparable installations. Finally, energy fed into the grid can be monitored. A web-based application can also be used for a web 2.0 forum for exchanging data with other forum users and for exchanging data in the forum, whereby a simple configuration of the forum in the web with input data of location, roof orientation and pitch, major components can be provided. It is also conceivable to calculate payments based on a basic rate plus usage charge and on a service level which can be determined by the web-based application.

According to another favorable embodiment, power performance data of at least one DAM and/or inverter measuring module can be compared with one or more power performance data patterns based on historical data, wherein each of said power performance data patterns can be assigned to a specific maintenance notice, and whereby said maintenance notice is generated if comparison of power performance data of said power generation module matches a specific power performance data pattern. Such a comparison between power performance data and one or more prestored power performance data patterns based on historical data can be performed either in a DMI (local) or in a power performance monitoring unit (centralized), and helps indicating a certain kind of malfunction, such as age-related degradation, shadowing, soiling, short-circuit or breakdown of a power generation module or malfunction of an inverter, so that a specific maintenance notice can be generated indicating cause of malfunction. Said maintenance notice can be sent to a maintenance service team or a provider for initiating a maintenance action restoring power performance of the affected power generation device.

According to another favourable embodiment, a maintenance notice can be generated signaling if power performance data values of a power generation device are low for a predefined time compared with historical values and/or compared with power performance data values of other comparable power generation devices. In this way, a maintenance notice can be generated only in case if such malfunction state exists longer than a predefined time and deviates significantly from historical values or from performance values of comparable power generation devices for a longer time-span, thus reducing false alarms and eliminating temporary malfunction effects, such as shadowing from a vehicle or temporary contamination by leaves which will be blown away by wind.

Another aspect of the invention proposes a program product comprising a computer useable medium including a computer readable program, wherein the computer readable program when executed on a computer causes the computer to perform one of the aforementioned embodiments of the inventive method. Specifically a part of said program being executed on a computer of a data interface module of at least one or more power generation devices causes the computer to perform the following steps of accessing power performance data comprising a module ID from each of one or more data acquisition modules via power line communication and each of one or more inverter measuring modules, preferably via power line communication; storing, analyzing and autonomously sending power performance data and/or maintenance notice based on at least a power performance pattern for requesting a maintenance action to at least one external power performance monitoring unit via an external network. Thus such a computer program product autonomously requests a specific maintenance action for a power generation module if power output of said power generation module differs from a specific power performance pattern. In this way an autonomously working monitoring and maintenance system is proposed which allows to optimize power performance and to reduce maintenance costs.

### BRIEF DESCRIPTION OF THE DRAWINGS

The present invention together with the above-mentioned and other objects and advantages may best be understood from the following detailed description of the embodiments, but not restricted to the embodiments, wherein is shown in:

FIG. 1 a monitoring system for power grid distributed power generation devices according to a first embodiment;

FIG. 2 a schematic view depicting a second embodiment of a monitoring system;

FIG. 3 two alternative possibilities for measuring solar module performance by a data acquisition module;

FIG. 4 a schematic view of a third embodiment of a monitoring system;

FIG. 5 a schematic view of an internal configuration of a data interface module;

FIG. 6 a schematic view of an internal configuration of a power performance monitoring unit;

FIG. 7 a structure of a power performance data packet and power performance data entry stored in a database of a data interface module or a power performance monitoring unit.

In the drawings, like elements are referred to with equal reference numerals. The drawings are merely schematic representations, not intended to portray specific parameters of the invention. Moreover, the drawings are intended to depict only typical embodiments of the invention and therefore should not be considered as limiting the scope of the invention.

### DETAILED DESCRIPTION OF EXAMPLE EMBODIMENTS

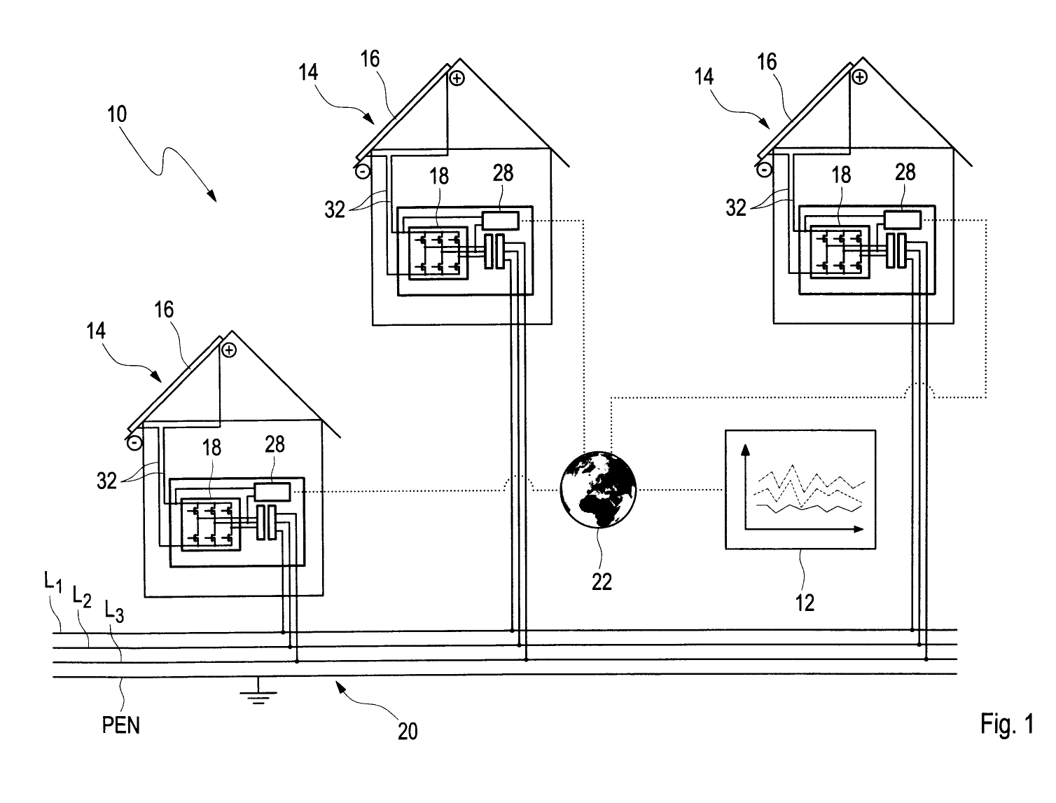

FIG. 1 depicts a monitoring system 10 comprising three groups of solar cell modules installed on a roof of a house representing power generation devices 14. Each power generation device 14 comprises a group of power generation modules 16—a group of solar cell modules—being connected by DC power lines 32 to an inverter module 18. The inverter module 18 converts DC power generated by said solar cell modules into AC power for feeding the generated electric power via a three-phase transformer into a power grid 20 comprising three phases L1, L2, L3 and a combined neutral and grounding conductor PEN. Each power generation device 14 comprises a data interface module 28, being connected to DC power line 32, whereby (not shown) a DAM measures power performance of each solar module and transmits power performance data via power line communication over DC power line 32 to data interface module 28. Furthermore, (not shown) an inverter measuring module measures AC output power of inverter module 18, whereby power performance data of inverter module 18 is transmitted to data interface module 28 via a LAN connection cable (not shown). The DDI 28 is connected via an external network 22 to a power performance monitoring unit 12, which receives, stores and analyzes power performance of all power generation devices 14 connected to the external network 22.

The data interface module (DDI) 28 is centrally installed in each power generation device 14 and is connected to each data acquisition module (DAM) and to the inverter measuring module (AC power meter) via an internal network sensing performance data of power output, whereby the DDI module 28 includes a method, where it receives performance data of all DAM modules and determines if one or more performance data is out of range over a period of time compared to other DAMs or to historical values of the AC power meter. Responsive to this the DDI module triggers an alert to a user and/or a power grid provider, indicating source and type of the defect. The DDI module 28 also includes another method, where it receives performance data of the AC meter and determines if the performance data is degrading by comparing it to the accumulated performance data from all the DAMs, responsive to this the DDI module triggers an alert to the user and provider including the data indicating the defect. The DDI module includes another method to collect all data from each DAM and from the AC meter over a certain period of time and sends these data via external network 22 to a repository, which can be accessed by a user and provider to view the performance data of the entire system.

The system 10 comprises multiple users (each one running its own power generation device 14). The generated power is being fed into the power grid 20 of the power grid provider. A connection to an external network 22, such as the internet, is provided to:

a) trigger alerts and corrective actions in case that the power generation is not optimal or components are defective, and
b) provides reports which can be analyzed by a user and/or provider in order to determine the defectiveness of local power generation devices also in comparison to other local power generation devices.

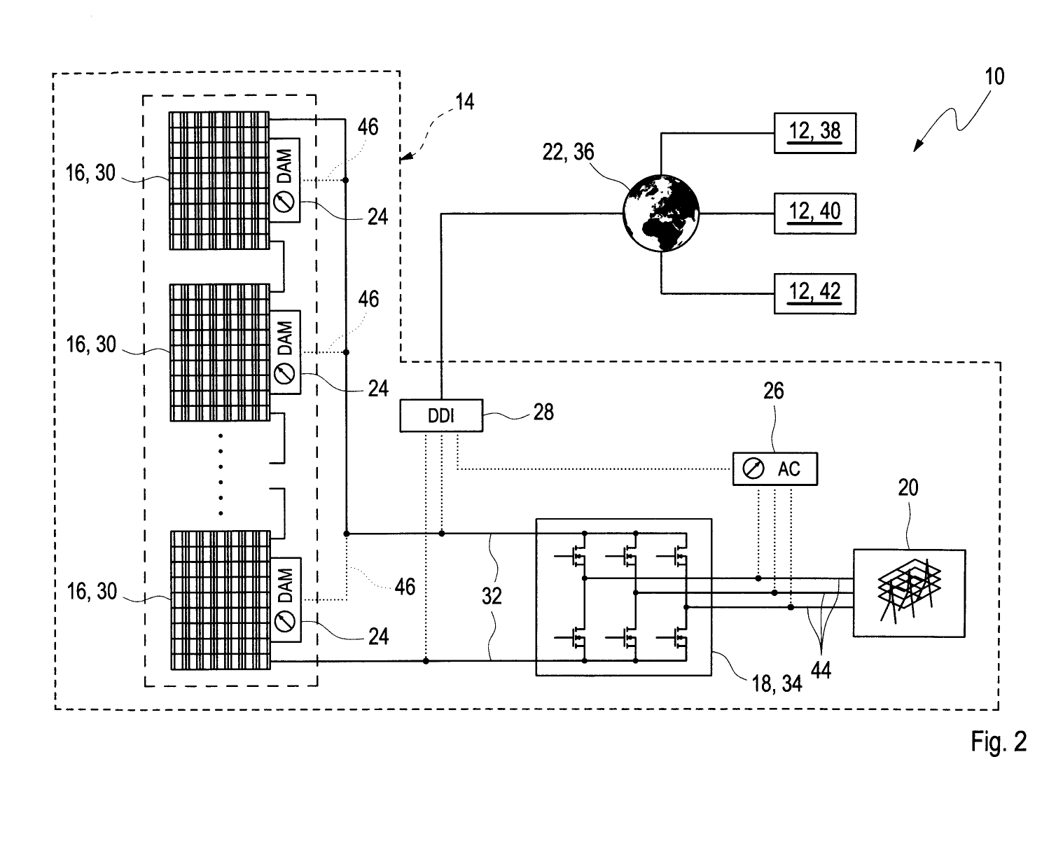

FIG. 2 shows a detailed embodiment of the internal structure of a monitoring system 10 comprising one power generation device 14. The power generation device 14 comprises several power generation modules 16 in the form of solar cell modules 30, each solar cell module 30 being equipped with a DAM 24 for measuring power output data of the attached solar cell module 30. The output DC power is transferred via a DC power line 32 to an inverter module 18 represented by a three-phase inverter 34 comprising six semiconductor power switches for converting DC power into three-phase AC power for feeding the generated energy via a three-phase power line 44 into a power grid 20. Power performance data and optionally other module data, preferably physical module data like temperature, sun light intensity, sun light angle (position of the sun), humidity, wind velocity and direction, transparency of a solar module surface, etc. measured by DAMs 24 are fed into the DC power line 32 via power line communication channels 46. Furthermore, output AC power via the three-phase power line 44 is measured by an AC meter representing an inverter measuring module 26. A DDI 28 is connected to DC power line 32 for power line communication and receives power performance data of the DAMs 24. Besides, DDI 28 is connected to the inverter measuring module 26 for receiving power performance data of energy outputted via three-phase power line 44. The DDI 28 stores and analyzes power performance data and sends power performance data and also maintenance notices in case that changes in power performance data indicate a certain malfunction of power generation module or inverter via internet representing an external network 22 to several power performance monitoring units 12, which are a user accessible monitoring unit 38, a provider accessible monitoring unit 40 and a repository 42 for storing and analyzing power performance data and maintenance notices.

Thus, FIG. 2 depicts an embodiment of a monitoring system 10 comprising a plurality of solar modules 30 generating electric power, whereby each solar module 30 has a data acquisition and RF modulation module (DAM) 24 attached thereto. The solar modules 30 generate electric power which is directed to the inverter 34 via a DC power network 32. The DAM modules 24 measure the power output of the solar module 30 in a digital way and modulate the data on the DC power network 32. The DC power network 32 connects the plurality of solar modules including DAMs to the power inverter 34 which converts DC current into AC current and to the demodulator and data interface module (DDI) 28 which uses data modulated by the DAM modules 24.

At the AC site of the power inverter, a three-phase power line 44 feeds electric power into a power grid 20, whereby an AC meter 26 measures the AC power output in a digital way and transmits this to the DDI module 28 via an internal network connection.

DAM modules 24 measure voltage and current generated by solar modules 30 and can also measure optional physical module data like cell/module temperature, etc. in a digital way. The digital data is embedded into digital packages modulated on the DC power network 32, which connects the solar module 30 and DAM modules 24 to the inverter 34. DDI module 28 uses a power line communication according to prior art, where digital data is frequency-modulated on a power line connection. Alternatively, another type of internal digital network, such as LAN, serial bus connection etc. can be used for connecting DAMs 24, DDI 28 and AC meter 26.

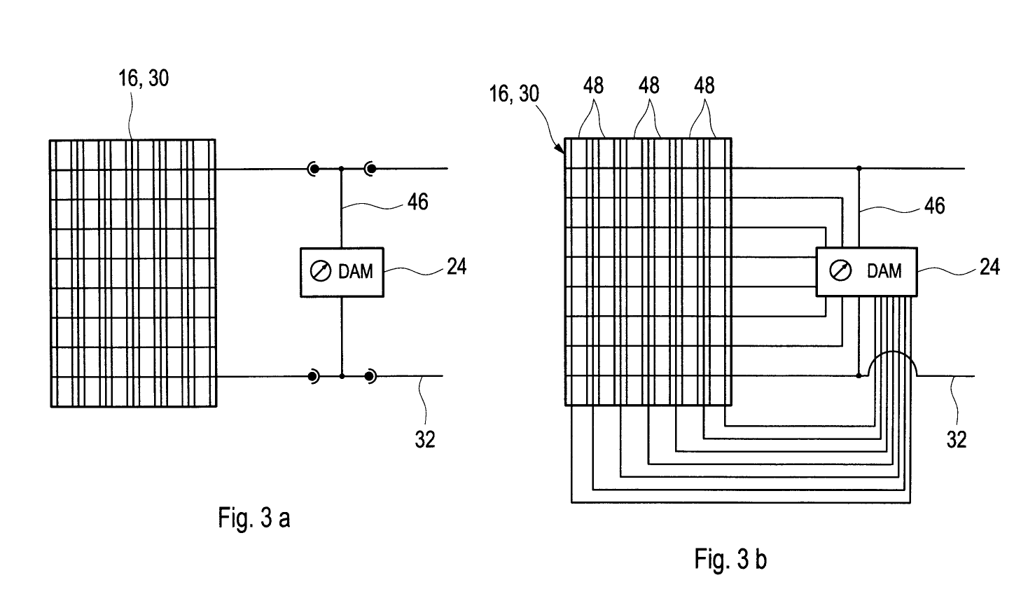

FIGS. 3a and 3b display two possibilities for connecting a DAM 24 to a solar module 30 for measuring power output of a power generation device 16. FIG. 3a depicts an overall measuring connection of a DAM 24 to a DC power line 32 of a solar module 30. The DAM module 24 measures the overall power generated by solar cell module 30, so that only two connections between solar cell module 30 and DAM 24 are required.

According to FIG. 3b, a DAM module 24 measures individual power output of each solar cell 48 of the solar cell module 30 or measures power output of a group of cells comprised by the solar cell module 30. DAM also delivers e.g. cell/module temperature data, sun light intensity and angle data, humidity data, wind velocity and direction data, transparency data of cell/module coating surface layer, full or partial shadowing data, etc., in case sensors are installed on cell and/or module level. Furthermore, DAM 24 is connected to the DC power line 32 via a power line communication channel 46. Such a configuration allows a more granular determination of power output of a solar cell module 30 and indicates malfunction of individual solar cells or groups of solar cells comprised by a solar cell module 30.

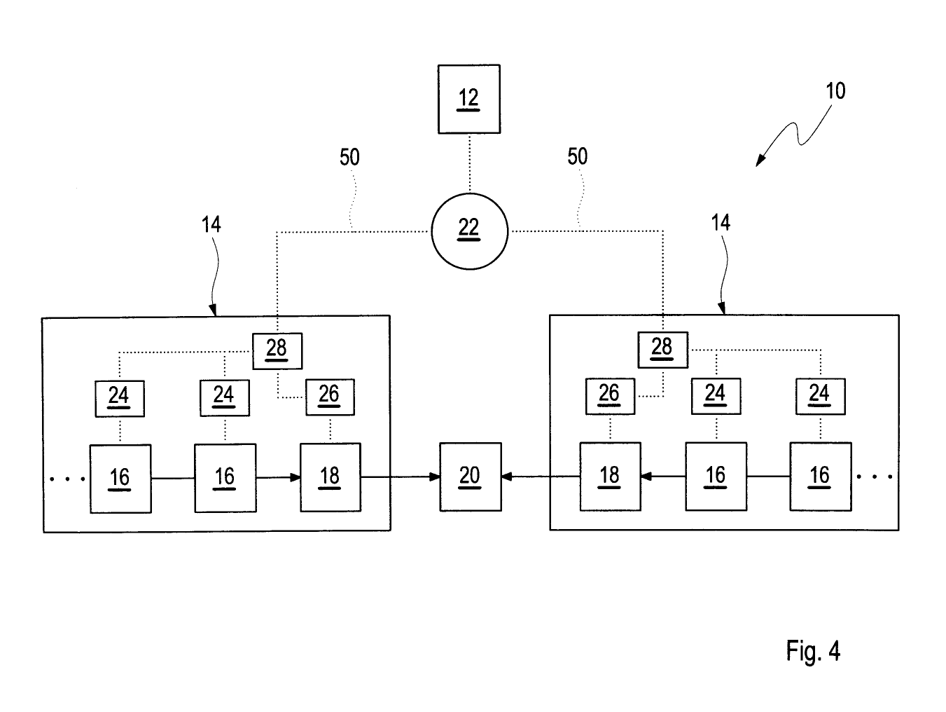

FIG. 4 depicts schematically another embodiment of a monitoring system 10 comprising two power generation devices 14 connected to a power performance monitoring unit 12 via an external network 22. Each power generation device 14 comprises at least two power generation modules 16 representing a renewable power source as a windmill or a solar cell module. For feeding a power grid 20 with AC power, each power generation device 16 comprises a power inverter 18 which converts DC power generated by the power generation modules 16 into AC power. Each power generation module 16 is connected to a DAM 24 for measuring DC power output and each inverter 18 is connected to an inverter measuring module 26 for measuring AC power output. The DAMs 24 and the inverter measuring module 26 are connected to a DDI 28 for collecting, storing and analyzing power performance data of the power generation module 16 and the power inverter 18. Each data interface module 28 is connected via a digital data packet based communication line 50 to an external network 22 which can be an internet network, a local area network (LAN), a radio network like WiMax, a power line network or other external networks. Attached to network 22 one or more power performance monitoring units 12 receives data of each power generation device 14 for storing and analyzing power performance of each power generation device 14 and for automatically informing a provider or a user by a maintenance notices in case of a malfunction of a power generation device 14.

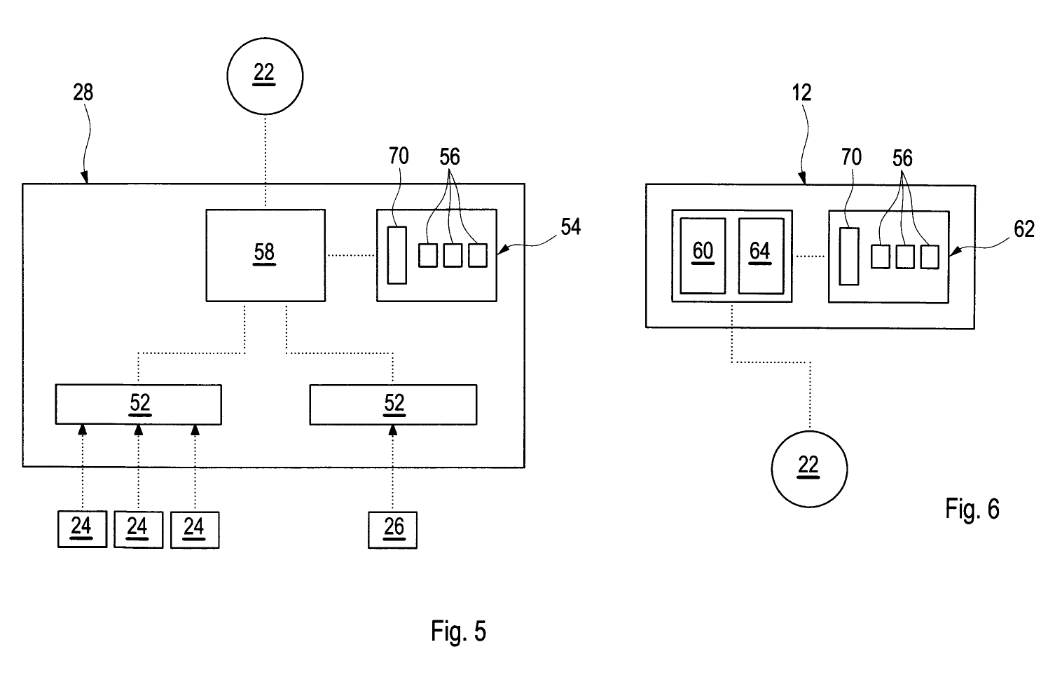

FIG. 5 displays in a schematic representation an internal configuration of a DDI 28. Three DAMs 24 are connected with the DDI 28 via a power line channel, whereby an internal power line communication decoder 52 decodes digital data received from each data acquisition modules 24. Furthermore, an inverter measuring module 26 is connected to the DDI 28 via another power line communication channel using an AC power line. Thus, a second power line communication decoder 52 decodes power performance data received by the inverter measuring module 26. Both power line communication decoders 52 are connected to a power performance analyzing unit 58, which analyzes the received power performance data, whereby the power performance analyzing unit 58 stores performance data and analyzed results in a power performance data memory 54. The power performance data memory 54 comprises a memory for storing historical power performance data 70 and also memory units 56 for storing predefined power performance data patterns indicating certain malfunction scenarios of the power generating modules or the inverter. Analyzing power performance data is based on comparing received power performance data with historical power performance data stored in data memory 54 and comparing these data with data patterns 56 indicating degradation or malfunction due to certain failure causes. As a result of such an analysis, power performance analyzing unit 58 sends a maintenance notice via an external network 22 to a provider, a user or a repository, thus signaling a need to carry out a specific maintenance action in order to recover power performance of the power generation device 14.

FIG. 6 shows schematically an internal configuration of a power performance monitoring unit 12 receiving power performance data and maintenance notices of one or several power generation devices 14 via an external network 22. Power performance monitoring unit 12 comprises a power generation module database 62 for storing power performance data in a certain memory unit 70 and also for storing power performance data patterns in certain memory units 56 indicating specific malfunction behavior for automatic generation of a maintenance notice. A web application server 60 grants access of a user, a provider or a repository to data stored in power generation module database 62 and a maintenance analyzing unit 64 analyzes power performance data by comparing these data with historical values 70 stored in database 62 and also by comparing power performance data 70 with pre-stored power performance data patterns 56 indicating certain causes of malfunction.

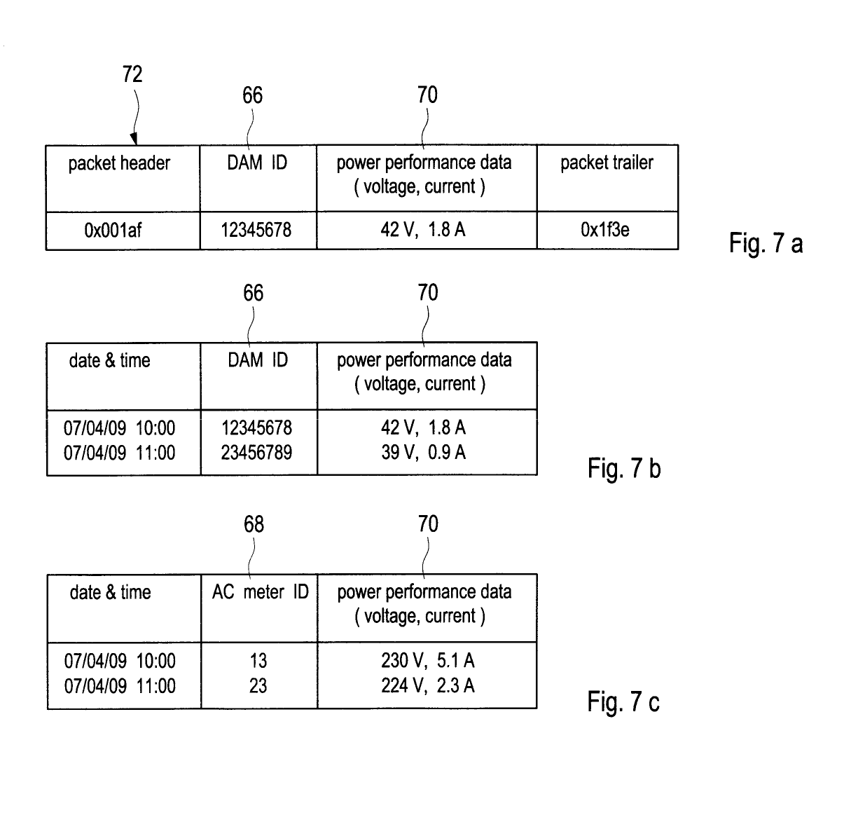

FIG. 7a displays a structure of a digital power performance data packet 72, which can be used for transferring power performance data from a DAM 24 or an inverter measuring module 26 to a DDI 28 or to transfer power performance data from a DDI 28 via an external network 22 to a power performance monitoring unit 12. The data packet 72 comprises a packet header and a packet trailer indicating type of data packet, check sum, source address assigned to a power generation device, time stamp, a check sum for checking integrity of the data. Furthermore, data packet 72 comprises a power generation module ID identifying the ID of the DAM, which sends the power performance data, and a power performance data block comprising at least a voltage and a current value, but can also comprise additional data such as generated electric power, hours of active service, temperature etc. The structure of the data packet 72 can be similar to that of a TCP/IP protocol. DAMs 24 as well as the inverter measuring unit 26 can be configured to send power data included in the packets shown in FIG. 7a periodically, such as once an hour.

FIG. 7b and FIG. 7c display structures of power performance data entries stored in a power performance data memory 52 of a DDI 28 or in a power generation module database 62 of a power performance monitoring unit 12. The memory entry of FIG. 7b belongs to data values of several DAMs 24, and the memory entry of FIG. 7c belongs to data values of several inverter measuring modules 26. Thereby, the data entries comprise a day and time stamp, a power generation module ID 66 or an inverter ID 68 and block of power performance data including voltage and current. According to FIG. 7b, DAM with ID 12345678 measures e.g. a voltage of 42 Volts and a current of 1.8 Ampere on Jul. 4, 2009 at 10:00 hrs. Another data entry of DAM with ID 234567898 measures 39 Volts and 0.9 Ampere at the same date one hour later.

In one embodiment a DDI module 28 is connected via an internal network such as LAN to an inverter measuring unit 26 measuring outgoing AC power, in this case voltage and current, in a digital manner. The DDI module 28 stores the received data values of the inverter measuring unit 26 in a power performance data memory 54. Thereby, as depicted in FIG. 7c, col. 1 of the memory entry contains day and time of measurement, here Jul. 4, 2009 at 10/11 o'clock. Col. 2 includes IDs of the AC meter. If there are multiple inverters installed in a single power generation device 14, multiple AC meters are required, typically one for each inverter. Col. 3 includes measured values (Volts and Ampere) which have been measured by the AC meter at the aforementioned dates and times.

The DDI module 28 can additionally include logic (software) being represented as power performance analyzing unit 58 which is able to perform at least one of the following methods:

Analyzing the power values of each DAM 24 including historical data and data from other DAMs 24 and deriving corrective actions;
Analyzing the power values from the inverter measuring module 26, compare this with historical data including data from DAM modules 24 and deriving corrective actions, whereby the sum of power performance data of DAM modules 24 should correspond to power performance measured by the inverter measuring module 26;
Creating status reports of the power values of the DAMs 24 and the inverter measuring module 26 and send this to a central repository 42 which can be accessed by a user 38 and/or a provider 40.

Method 1 analyzes a power generation module performance data and derives corrective actions, whereby a DDI module 28 receives, demodulates and stores the power value data from all DAMs 24 periodically in a table depicted in FIG. 7b. Periodically (e.g. once a day) or when triggered by a power performance monitoring unit 12, a DDI 28 performs the following method:

for given dates and times (col. 1 of FIG. 7b) analyzing power data of all DAMs 24 by comparing the power data (col. 3) for all DAMs 24;
determine a DAM 24 with the lowest power data values;
determine if the power data values 70 of said DAM 24 are low for a longer period of time by comparing additional power values for different periods of time and different DAMs 24 to said DAM 24;
if the power values of said DAM 24 are low, then send an alert to the provider and user including the power values of said DAM 24 and power values of other DAMs 24 and a message that some power generation modules 16 are not performing well. Optionally, if the DAM data indicate that some cells or the module run at elevated temperature, at bad solar light angle, at increased mechanical stress due to excessive wind blast or at other unfavorable physical conditions a notification has to be issued to initiate e.g. maintenance or repair actions.

This method allows an autonomous detection of degradation of power generation modules 16 over time and sends an alert to a provider which will trigger manual maintenance actions, e.g. replacement of a defective power generation module 16, especially a solar module.

Method 2 is designed to analyze power generation device AC output performance and derive corrective actions. Thereby DDI module 16 receives and stores power value data 70 from an inverter measuring module 26, especially an AC meter periodically. Periodically (once a day) or when triggered by a power performance monitoring unit 12, DDI 28 performs the following method:

for given dates and times analyze power data from inverter measuring module 26 by comparing the power data from the inverter measuring module 26 to the accumulated power data from all DAMs 24;
determine if the power data from the inverter measuring module 26 decreases;
if this is the case, send an alert to a provider and user including the power values of all DAMs 24 and power values of other DAMs 24 and message that a power inverter module or some power generation modules are not performing well.

This method allows detection of the degradation of power inverter module 18 over time by comparing inverter input (via a sum of DAM values of connected power generation modules 16) to inverter output (via inverter measuring unit 26, especially AC meter) and sends an alert to a provider which will cause manual maintenance actions, e.g. replacement of the defective inverter 18.

Method 3 creates and sends a status report. A DDI module 28 can be configured to send a maintenance notice including data of FIG. 7b and FIG. 7c periodically to a repository 42 including a power performance monitoring unit 12 via an external network 22. Thereby, a method as follows can be used:

determine if a time interval for sending a maintenance notice of power performance status report is reached; gather data from power performance data memory 54 and send it to the repository 42 over an external network 22.

This method allows a user and/or provider to view the power performance data of a power generation module 16 and a power inverter module 18. The data stored in the repository 42 might be accessible via a worldwide web application. The representation of the power values 70 of power generation modules 16 and inverters 18 can be represented in any textual or graphical way and can be used for analyzing power performance and for calculating a billing of energy fed into a power grid 20.

The monitoring system 10 discussed above is not limited to solar applications but could be used in all renewable energy applications. A detailed data and power performance visibility helps to manage the power generation device installation as well as proactively or reactively perform corrective actions. Problems such as device degradation and other fallout criteria, e.g. shadowing effects and contamination can be determined early and quickly resolved. Maintenance can be scheduled much more appropriately according to the module/inverter performance. Information on the performance of power generation devices is in real-time and autonomously available. In case of any incidence or problem, a maintenance notice can be generated to inform a provider or a user to take maintenance actions. The entire data can be viewed using a web application without the need of installing additional software on a computer. The invention represents a smart solution to manage renewable energy sources much more efficiently and in real-time. This is to maximize energy output and optimize related costs for a user and a provider.

The invention can take the form of an entirely hardware embodiment, an entirely software embodiment or an embodiment containing both hardware and software elements. In a preferred embodiment, the invention is implemented in software, which includes but is not limited to firmware, resident software, microcode, etc.

Furthermore, the invention can take the form of a computer program product accessible from a computer-usable or computer readable medium providing program code for use by or in connection with a computer or any instruction execution system. For the purposes of this description, a computer-usable or computer readable medium can be any apparatus that can contain, store, communicate, propagate, or transport the program for use by on in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read-only memory (CD-ROM), compact disk-read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O-devices (including, but not limited to keyboards, displays, pointing devices, etc.) can be coupled to the system either directly or through intervening I/O controllers.

Network adapters may also be coupled to the system to enable the data processing system or remote printers or storage devices through intervening private or public networks. Modems, cable modem and Ethernet cards are just a few of the currently available types of network adapters.

1. An autonomous monitoring system for power grid distributed power generation devices comprising
at least one power performance monitoring unit for monitoring, analyzing and storing at least power performance data of at least one power generation device;
at least one power generation device comprising at least one power generation module for generation of electric power and at least one inverter module for feeding in electric power of said power generation module to a power grid (20); and
an external network connecting one or more power generation devices with said power performance monitoring unit; characterized in that the power generation device further comprises at least one data acquisition module for measuring of power output of each power generation module;
at least one inverter measuring module for measuring of power output of said inverter to the power grid; and
a data interface module in power-line communication with said data acquisition module and in communication with said inverter measuring module and said external network for sending power performance data of said power generation device to said power performance monitoring unit including power generation module ID and inverter ID and/or for autonomously sending a maintenance notice for requesting a maintenance action based on at least a specific power performance pattern.

2. The system according to claim 1, wherein the power generation module comprises a DC power generation module, preferably a renewable DC power generation module, particularly a solar cell module; and
the inverter comprises a DC/AC inverter, preferably a 3 phase inverter.

3. The system according to claim 2, wherein the power generation module comprises one or more power generation cells, preferably solar cells, and the data acquisition module measures power output of at least one cell or a group of cells of the power generation module.

4. The system according to claim 3, characterized in that at least the data acquisition module and the inverter measuring module outputs digital power performance data comprising voltage and current values and is connected to the data interface module via a power line communication (PLC) channel.

5. The system according to claim 4, wherein the data interface module comprises a power performance data memory for storing of power performance data of at least one data acquisition module and/or inverter measuring module.

6. The system according to claim 5, wherein the data interface module comprises a power performance analyzing unit for analyzing power performance data of at least one data acquisition module and/or inverter measuring module based on at least a specific power performance pattern and for creating and sending power performance data and/or a maintenance notice over the external network to said power performance monitoring unit.

7. The system according to claim 6, characterized in that the power performance monitoring unit comprises a network application server, especially a web application server, allowing autonomous update, monitoring, evaluation of power performance data and/or of maintenance notice of at least one power generation device over a network.

8. The system according to claim 7, wherein the power performance monitoring unit comprises a power generation module database for storing of power performance data and/or maintenance notice of at least one power generation device over a period of time and/or comprises a maintenance analyzing unit for generating and signaling a maintenance notice of a power generation device over a network.

9. A method for autonomous maintenance of distributed power generation devices in a power grid, comprising:
accessing power performance data comprising a module ID from each of one or more data acquisition modules via power line communication and each of one or more inverter measuring modules, preferably via power line communication, by a data interface module of each of one or more power generation devices;
storing, analyzing and autonomously sending power performance data and/or maintenance notice based on at least a power performance pattern for requesting a maintenance action by the one or more data interface modules to at least one power performance monitoring unit via an external network;
providing said maintenance action assigned to said maintenance notice.

10. The method according to claim 9, wherein accessing power performance data from at least one data acquisition module and/or inverter measuring module by the data interface module is performed using a packet oriented data protocol, wherein each packet comprises at least a packet header, a source address, a power performance data block including voltage and current values and a packet trailer.

11. The method according to claim 10, wherein accessing power performance data and/or sending power performance data and/or maintenance notice is performed either periodically or by request from the data interface module or the power performance monitoring unit respectively.

12. The method according to claim 11, wherein power performance data and/or maintenance notice of at least one power generation module can be accessed through a network, preferably internet by a network application, preferably a web application hosted by a power performance monitoring unit.

13. The method according to claim 12, wherein power performance data of at least one data acquisition module and/or inverter measuring module is compared with one or more power performance data pattern based on historical data, wherein each of said power performance data patterns is assigned to a specific maintenance notice and whereby said maintenance notice is generated if the comparison of the power performance data of said power generation module matches within a specific power performance data pattern.

14. The method according to claim 13, wherein
a maintenance notice is generated and signaled if power performance data values of a power generation device are low for a predefined time compared with historical values and/or power performance data values of other comparable power generation devices.

15. A program product comprising a computer useable medium including a computer readable program, wherein the computer readable program when executed on a computer of a data interface module of at least one or more power generation devices causes the computer to perform the following steps:
accessing power performance data comprising a module ID from each of one or more data acquisition modules via power line communication and each of one or more inverter measuring modules, preferably via power line communication;
storing, analyzing and autonomously sending power performance data and/or maintenance notice based on at least a power performance pattern for requesting a maintenance action to at least one external power performance monitoring unit via an external network.
